(19) United States
(12) Patent Application Publication
(10) Pub. No.: US 2026/0020151 A1
(43) Pub. Date: Jan. 15, 2026

(54) PRINTED CIRCUIT BOARD

(71) Applicant: SAMSUNG ELECTRO-MECHANICS CO., LTD., Suwon-si (KR)

(72) Inventors: Tae Kyung LEE, Suwon-si (KR); Je Hong KYOUNG, Suwon-si (KR); Jin Uk LEE, Suwon-si (KR); Kwang Su KIM, Suwon-si (KR); Joung Hun KIM, Suwon-si (KR)

(73) Assignee: SAMSUNG ELECTRO-MECHANICS CO., LTD., Suwon-si (KR)

(21) Appl. No.: 19/046,164

(22) Filed: Feb. 5, 2025

(30) Foreign Application Priority Data
Jul. 15, 2024 (KR) 10-2024-0093209

(51) Int. Cl. H05K 1/09; H01L 23/498

(52) U.S. Cl. CPC H05K 1/09; H01L 23/49866

(57) ABSTRACT

A printed circuit board including: a conductive pattern including a seed metal layer and a pattern metal layer disposed on the seed metal layer, and the seed metal layer includes a first metal layer including a first metal, and a second metal layer disposed on the first metal layer and connected to the pattern metal layer and including a second metal, the first metal layer has a thickness thicker than the second metal layer, and the first metal is one selected from the group consisting of aluminum (Al), iridium (Ir), molybdenum (Mo), tungsten (W), cobalt (Co), nickel (Ni), and ruthenium (Ru).

### CROSS-REFERENCE TO RELATED APPLICATION(S)

This application claims benefit of priority to Korean Patent Application No. 10-2024-0093209 filed on Jul. 15, 2024, in the Korean Intellectual Property Office, the disclosure of which is incorporated herein by reference in its entirety.

### TECHNICAL FIELD

The present disclosure relates to a printed circuit board.

Demand for multi-chip packages having multiple chips such as memory, CPU, and GPU on a substrate has increased. Specifically, demand for package substrates for AI servers has rapidly increased. In relation thereto, the input/output ports of chips are increasing, and high wiring density is required on the substrate. Meanwhile, in forming micropatterns, not only plating technology but also seed metal layer formation and removal technology are becoming more important. Specifically, the technology for plating and patterning micropatterns on an organic insulating layer may be considered to have high technical difficulty. For example, in the case of copper, patterning may be basically possible through a wet etching process, and in this case, in order to form an electroplating film as a thick film, a thickness of a seed layer for plating should be sufficiently secured to enable stable plating. However, as the seed layer becomes thicker, the wet etching time for etching and removing the seed layer may increase. When the seed layer etching time increases, an undercut may be formed as the seed layer is etched first, and in this case, delamination may occur between a micropattern and the organic insulating layer.

### SUMMARY

An aspect of the present disclosure is to provide a printed circuit board including a conductive pattern that is unlikely to cause delamination when etching a seed metal layer for plating.

Another aspect of the present disclosure is to provide a printed circuit board including the conductive pattern including a plurality of micropatterns.

One of the various solutions proposed through the present disclosure is to form a plurality of metal layers as a seed metal layer in a conductive pattern including a seed metal layer and a pattern metal layer, and to form one of these metal layers to be thicker than the other metal layers by utilizing a metal that is different from the metal mainly included in a pattern metal layer but which has high electrical conductivity.

For example, a printed circuit board according to an example embodiment may include a conductive pattern including a seed metal layer and a pattern metal layer disposed on the seed metal layer, and the seed metal layer may include a first metal layer including a first metal, and a second metal layer disposed on the first metal layer and connected to the pattern metal layer and including a second metal, the first metal layer may have a thickness thicker than the second metal layer, and the first metal may be one selected from the group consisting of aluminum (Al), iridium (Ir), molybdenum (Mo), tungsten (W), cobalt (Co), nickel (Ni), and ruthenium (Ru).

For example, a printed circuit board according to an example embodiment may include: an insulating substrate; and a conductive pattern including a seed metal layer disposed on the insulating substrate and a pattern metal layer disposed on the seed metal layer, and the seed metal layer may have a stack structure including a titanium (Ti) layer, a molybdenum (Mo) layer, and a first copper (Cu) layer stacked in order.

As one of the various effects of the present disclosure, a printed circuit board including a conductive pattern that is unlikely to cause delamination when etching a seed metal layer for plating may be provided.

As another of the various effects of the present disclosure, a printed circuit board including such a conductive pattern including a plurality of micropatterns may be provided.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIG. 4 is a process diagram schematically illustrating an example of manufacturing the printed circuit board of FIG. 3;

FIG. 5 is a cross-sectional view schematically illustrating another example of a printed circuit board;

FIG. 6 is a process diagram schematically illustrating an example of manufacturing the printed circuit board of FIG. 5;

FIG. 7 is a cross-sectional view schematically illustrating an example of a semiconductor package; and

FIG. 8 is a cross-sectional view schematically illustrating another example of a semiconductor package.

### DETAILED DESCRIPTION

Hereinafter, the present disclosure will be described with reference to the accompanying drawings. In the drawings, the shape and size of the elements may be exaggerated or reduced for clearer description.

### Electronic Device

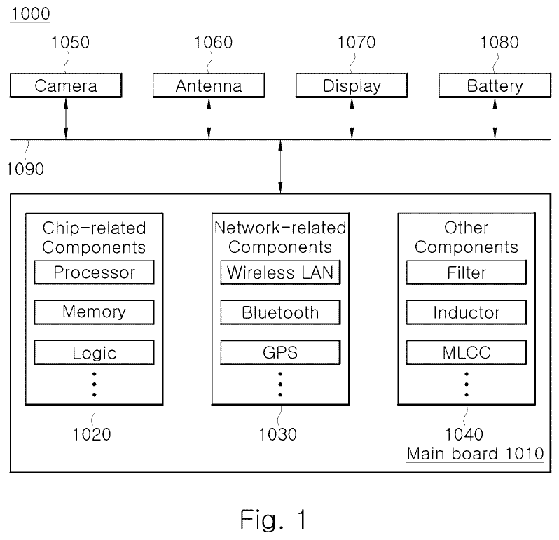

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

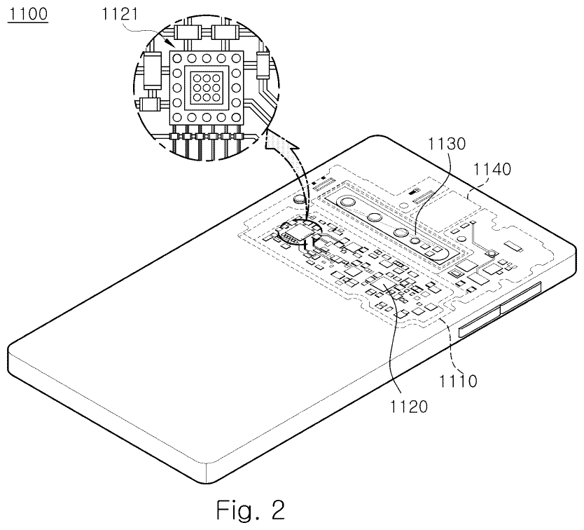

FIG. 2 is a perspective view schematically illustrating an example of an electronic device.

Referring to FIG. 2, an electronic device may be, for example, a smartphone 1100. A mother board 1110 may be accommodated in the smartphone 1100, and various components 1120 may be physically and/or electrically connected to the mother board 1110. Furthermore, other components that may or may not be physically and/or electrically connected to the mother board 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may have the form of a printed circuit board in which an electronic component including an active component and/or a passive component is mounted on a surface. Alternatively, the component package 1121 may have the form of a printed circuit board in which an active component and/or a passive component are embedded. On the other hand, the electronic device is not necessarily limited to the smartphone 1100, and may be other electronic devices as described above.

### Printed Circuit Board

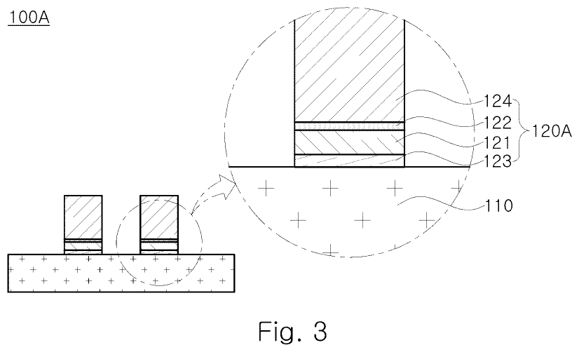

FIG. 3 is a cross-sectional view schematically illustrating an example of a printed circuit board.

Referring to FIG. 3, a printed circuit board 100A according to an example embodiment may include an insulating substrate 110 and a plurality of conductive patterns 120A disposed on an insulating substrate 100. Each conductive patterns 120A may include seed metal layers 121, 122 and 123 and a pattern metal layer 124 disposed on the seed metal layers 121, 122 and 123. The seed metal layers 121, 122 and 123 may include a first metal layer 121 including a first metal, a second metal layer 122 including a second metal, and a third metal layer 123 including a third metal. Based on a thickness direction, the third metal layer 123, the first metal layer 121, and the second metal layer 122 may be stacked in order.

Meanwhile, the first metal may be different from a metal mainly included in the pattern metal layer 124 but may have high electrical conductivity. For example, the first metal may have an electrical resistivity of 10×10⁻⁸ Ω*m or less, and more specifically, the first metal may be one selected from the group consisting of aluminum (Al), iridium (Ir), molybdenum (Mo), tungsten (W), cobalt (Co), nickel (Ni), and ruthenium (Ru). Additionally, the second metal may be the same as a metal mainly included in the pattern metal layer 124, and may have a lower electrical resistivity than the first metal. For example, the pattern metal layer 124 may include copper (Cu), and the second metal may be copper (Cu). Additionally, the third metal may be a metal having excellent adhesion to the insulating layer and may have a higher electrical resistivity than the first metal. For example, the third metal may be one selected from the group consisting of chromium (Cr), tantalum (Ta), niobium (Nb), and titanium (Ti).

For example, the second metal layer 122 in contact with the pattern metal layer 124, among the seed metal layers 121, 122 and 123, may include the same second metal as the metal mainly included in the pattern metal layer 124, such as copper (Cu), and may be a sputter thin film formed by a sputtering process. In this case, when forming the pattern metal layer 124 by electrolytic plating, for example, electrolytic copper, nucleation on a surface may be facilitated, and thus the plating may proceed smoothly. Additionally, the second metal layer 122 may be formed to be thinner than the first metal layer 121, and may have a thickness of, for example, 1000 Å or less, or 50 Å to 1000 Å. Accordingly, occurrence of undercut and delamination may be prevented. Meanwhile, when a thickness of the second metal layer 122 is less than 50 Å, island growth may occur, which may cause adhesion problems during plating.

Additionally, the first metal layer 121 may be disposed below the second metal layer 122, and the first metal layer 121 may include the metal mainly included in the pattern metal layer 124, but may include the first metal such as aluminum (Al), iridium (Ir), molybdenum (Mo), tungsten (W), cobalt (Co), nickel (Ni) or ruthenium (Ru), which is different from the second metal such as copper (Cu), but has a high electrical resistivity of 10×10⁻⁸ Ω*m or less. In this case, the conductivity of an entire seed layer due to a thickness reduction of the second metal layer 122 may be compensated by the first metal layer 121 having high electrical conductivity, so that the plating can proceed more smoothly. Meanwhile, the first metal layer 121 may also be a sputter thin film formed in a sputtering process.

Additionally, a third metal layer 123 that may be in contact with at least one surface of the insulating substrate 110 may be disposed below the first metal layer 121. The third metal layer 123 may have excellent adhesion to the insulating layer, may have a higher electrical resistivity than the first metal, and may include a third metal that may have a lower electrical conductivity than the first metal, such as chromium (Cr), tantalum (Ta), niobium (Nb) or titanium (Ti). Additionally, the third metal layer 123 may be formed to be thinner than the first metal layer 121. In this case, the adhesion between the insulating substrate 110 and the conductive pattern 120A may be improved. Additionally, the occurrence of undercut and delamination may be prevented.

As a non-limiting example, the first metal layer 121 may be a molybdenum (Mo) layer, the second metal layer 122 may be a copper (Cu) layer, and the third metal layer 123 may be a titanium (Ti) layer, and thus, the seed metal layers 121, 122 and 123 may have a stack structure in which a titanium (Ti) layer, a molybdenum (Mo) layer, and a copper (Cu) layer are stacked in order, but the present application is not limited thereto. Meanwhile, a total conductance of the seed metal layers 121, 122 and 123 may be 350×10⁻² Ω⁻¹ or more, in which case, plating may be performed more easily. Meanwhile, the total conductance may be the sum of the conductivities of each of the first to third metal layers 121, 122 and 123 included in the seed metal layers 121, 122 and 123. Additionally, the conductivities of each of the first to third metal layers 121, 122 and 123 may be a value obtained by dividing each thickness by each electrical resistivity.

Meanwhile, the insulating substrate 110 may include an insulating material. The insulating material may include an organic insulating material and/or an inorganic insulating material. The organic insulating material may include a thermosetting resin such as an epoxy resin, a thermoplastic resin such as a polyimide, or a material including an inorganic filler, an organic filler, and/or glass fiber (Glass Fiber, Glass Cloth or Glass Fabric) together with the resin. For example, the organic insulating material may be a non-photosensitive insulating material such as Copper Clad Laminate (CCL), an (Ajinomoto Build-up Film (ABF), Prepreg (PPG), or the like, but the present disclosure is not limited thereto, and other polymer materials may be used as the organic insulating material. Additionally, the organic insulating material may be a photosensitive insulating material such as Photoimageable Dielectric (PID). The inorganic insulating material may be silicon (Si), glass, ceramic, or the like, but the present disclosure is not limited thereto, and other inorganic materials may be used.

Meanwhile, the plurality of conductive patterns 120A may be a plurality of micropatterns adjacent to each other, and in this case, a width of each micropattern and an interval between the micropatterns may be 2μm or less, or 1 μm or less, respectively. For example, the plurality of conductive patterns 120A may be a plurality of micropatterns having lines/spaces of 2μm/2μm or less, or 1 μm/1μm or less. Additionally, an aspect ratio of each of the micropatterns may be 1 or more. In this case, the micropatterns may be stably implemented by the configuration of the seed metal layers 121, 122 and 123 as described above. For example, the occurrence of undercut and delamination may be prevented, and the plating may proceed smoothly. The number of conductive patterns 120A is not particularly limited. The micropatterns described above may have a line shape and may be used as traces for signal transmission. Meanwhile, the conductive pattern 120A may further include a pad pattern or a plane pattern in addition to the line pattern, if necessary. Additionally, the conductive pattern 120A may further include a power pattern and/or a ground pattern in addition to a signal pattern, if necessary.

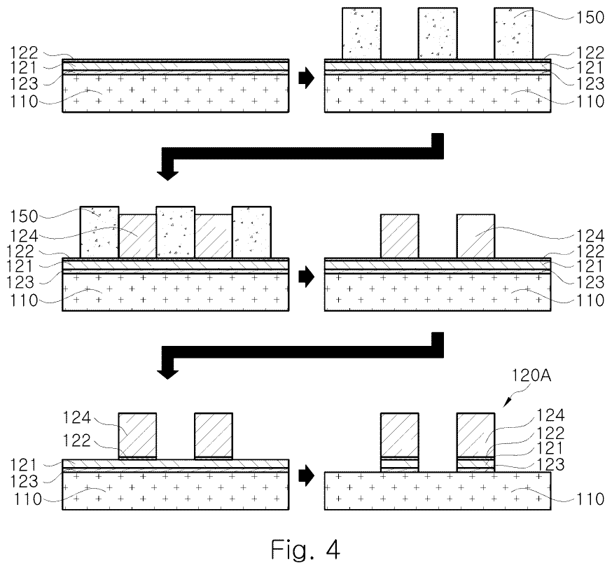

FIG. 4 is a process diagram schematically showing an example of manufacturing a printed circuit board of FIG. 3.

Referring to FIG. 4, first, seed metal layers 121, 122 and 123 are formed on an insulating substrate 110. The seed metal layers 121, 122 and 123 may be formed, for example, in a sputtering process (e.g., DC Sputter), respectively, and a third metal layer 123 as a bonding layer, a first metal layer 121 as a compensation layer, and a second metal layer 122 as a seed layer may be formed in this order. Next, a photoresist mold 150 is formed on the second metal layer 122, and a space for forming a microcircuit pattern is patterned by an exposure and development process, or the like. Next, a pattern metal layer 124 is formed on the second metal layer 122 exposed through an opening of the photoresist mold 150 by electrolytic plating, for example, electrolytic copper plating. Next, the photoresist mold 150 is stripped and removed. Next, the second metal layer 122 of an unnecessary region is removed by wet etching, for example, using an etchant. Next, the first metal layer 121 and the third metal layer 123 of an unnecessary region are removed by dry etching, for example, Reactive Ion Etching (RIE). Meanwhile, the first metal layer 121 and the third metal layer 123 may be removed simultaneously. Through such a process, a printed circuit board 100A according to an example embodiment having the above-described technical effect may be manufactured. Since other details are substantially the same as those described above, redundant descriptions thereof will be omitted.

Hereinafter, the technical effect of the printed circuit board 100A according to an example embodiment will be described in more detail through experiments.

### COMPARATIVE EXAMPLE

A titanium (Ti) layer and a copper (Cu) layer were deposited on an organic insulating layer with a thickness of about 500 Å and 2000 Å, respectively, in a sputtering process, thereby forming a seed metal layer having a stack structure. Next, a photoresist mold was patterned on the seed metal layer, and copper (Cu) was plated by a thickness of 2μm or more by electroplating, thereby forming a pattern metal layer including a fine circuit pattern having lines/spaces of 2 μm/2μm. Meanwhile, copper (Cu) has an electrical resistivity of about 1.72×10⁻⁸ Ω*m, and titanium (Ti) has an electrical resistivity of about 42×10⁻⁸ Ω*m, so that the total conductance of the seed metal layer was calculated to be about 1175×10⁻² Ω⁻¹. Meanwhile, a copper (Cu) electroplating was performed under the condition in which a copper sulfate aqueous plating solution was used, and the plating current density was 1ASD (Ampere per Square Decimeter) at which the current density per unit area of the substrate was 1A/(dm2). In this case, a sensed voltage was approximately 0.3 V. As described above, a total conductance of the seed layer was considerable, so that the copper (Cu) electroplating was performed without any problems. After the electroplating was completed, the photoresist mold was stripped and removed, and the seed metal layer was removed by wet etching to form a micropattern. For example, a copper (Cu) etchant was used, and while the seed copper (Cu) layer was removed, a thickness and a width of a copper (Cu) plating layer of the micropattern were reduced. Specifically, undercut occurred in the seed copper (Cu) layer during a wet etching of the seed copper (Cu) layer. Next, the seed titanium (Ti) layer was also removed by the etchant. When even the seed titanium layer (Ti) was removed, severe undercut occurred in a lower portion of the micropattern, and when the line/space was 2μm/2μm and the aspect ratio exceeded 1, delamination due to the undercut was severe.

### Example 1

In order to improve the problem of the comparative example, a seed metal layer was changed to a seed stack structure that may alleviate undercut during seed etching. Specifically, in order to reduce a thickness of the seed copper (Cu) layer, a molybdenum (Mo) layer having good conductivity was introduced. That is, a titanium (Ti) layer, a molybdenum (Mo) layer, and a copper (Cu) layer were deposited in this order on the organic insulating layer in a sputtering process at a thickness of about 500 Å, 1500 Å, and 500 Å, respectively, thereby forming a seed metal layer having a stack structure. Next, a photoresist mold was patterned on the seed metal layer, and copper (Cu) was electroplated by a thickness of 2μm or more, thereby forming a pattern metal layer including a fine circuit pattern having lines/spaces of 2μm/2μm. Meanwhile, a thickness of the copper (Cu) layer was reduced to ¼ as compared to the comparative example, but a molybdenum (Mo) layer, which is a compensation layer having an electrical resistivity of about 5.28×10⁻⁸ Ω*m, was added at a thickness of 1500 Å, so that the total conductance of the seed metal layer was calculated to be about 587×10⁻² Ω⁻¹. Meanwhile, the copper (Cu) electroplating conditions were the same as those in the comparative example. Accordingly, the total conductance of the seed metal layer was reduced as compared to the comparative example, but the copper (Cu) electroplating proceeded without a problem. After the electroplating was completed, the photoresist mold was stripped and removed, and the seed metal layer was etched to form a micropattern. For example, a copper (Cu) etchant was used to remove the seed copper (Cu) layer, and in this case, the etching time was significantly reduced as compared to the comparative example, so that the thickness and the width of the micropattern copper (Cu) plating layer were not significantly reduced. The titanium (Ti) layer as the bonding layer and the molybdenum (Mo) layer as the compensation layer were removed by dry etching, not wet etching. For example, a gas etchant that may etch the titanium (Ti) layer and the molybdenum (Mo) layer at once was used, and specifically, RIE was performed. In the RIE, a gas mixed with a fluorine-based material (CF4, CHF3, SF6, or the like.) and a chlorine-based material (C12, BC13, or the like) was used. Additionally, argon gas for plasma ion bombardment was also used. After dry etching, a final micropattern barely had any undercut due to the thickness reduction of the seed copper (Cu) layer, and the micropattern was also formed without delamination.

### Example 2

In order to confirm whether there was any problem with electroplating even when the thickness of the seed copper (Cu) layer was reduced more than in Example 1, the seed metal layer was changed. That is, a titanium (Ti) layer, a molybdenum (Mo) layer, and a copper (Cu) layer were deposited in this order on the organic insulating layer by a sputtering process by a thickness of about 500 Å, 1500 Å, and 300 Å, respectively, to form a seed metal layer having a stack structure. In this case, the total conductance of the seed metal layer was calculated to be about 470×10⁻² Ω⁻¹. The rest of the experiment was conducted in the same manner. Even though the thickness of the seed copper (Cu) layer was reduced, plating proceeded normally, and similarly, in a final micropattern, undercut due to the reduction in the thickness of the seed copper (Cu) layer was barely observed, and the micropattern was also formed without delamination.

### Example 3

In order to confirm whether there was no problem with electroplating even when the thickness of the seed copper (Cu) layer was reduced more than in Example 2, the seed metal layer was changed. That is, a titanium (Ti) layer, a molybdenum (Mo) layer, and a copper (Cu) layer were deposited in this order on the organic insulating layer by a sputtering process to by a thickness of about 500 Å, 1500 Å, and 100 Å, respectively, to form a seed metal layer having a stack structure. In this case, the total conductance of the seed metal layer was calculated to be about 354×10⁻² Ω⁻¹. The rest of the experiment was conducted in the same manner. Even though the thickness of the seed copper (Cu) layer was further reduced, plating proceeded normally, and similarly, in a final micropattern, undercut due to the reduction in the thickness of the seed copper (Cu) layer was barely observed, and the micropattern was also formed without delamination.

### Reference Example 1

In Example 1, the seed metal layer was changed to confirm whether there was no problem with electroplating even when the seed copper (Cu) layer was changed to a seed titanium (Ti) layer. That is, a titanium (Ti) layer, a molybdenum (Mo) layer, and a titanium (Ti) layer were deposited in this order on the organic insulating layer by a sputtering process by a thickness of about 500 Å, 1500 Å, and 500 Å, respectively, to form a seed metal layer having a stack structure. In this case, the total conductance of the seed metal layer was calculated to be about 308×10⁻² Ω⁻¹. The rest of the experiment was conducted in the same manner. Copper (Cu) was used for electroplating to form a micropattern, and when a seed titanium (Ti) layer is used instead of a seed copper (Cu) layer, this may be disadvantageous for copper (Cu) nucleation, and the total conductance may decrease. Therefore, plating failure may occur.

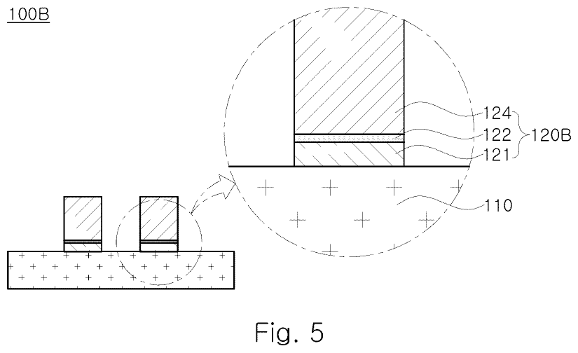

FIG. 5 is a cross-sectional view schematically illustrating another example of a printed circuit board.

Referring to FIG. 5, a printed circuit board 100B according to another example embodiment may include an insulating substrate 110 and a plurality of conductive patterns 120B disposed on the insulating substrate 100. Each conductive pattern 120B may include seed metal layers 121 and 122 and a pattern metal layer 124 disposed on the seed metal layers 121 and 122. The seed metal layers 121 and 122 may include a first metal layer 121 including a first metal and a second metal layer 122 including a second metal. Based on a thickness direction, the first metal layer 121 and the second metal layer 122 may be stacked in order. For example, as compared to a conductive pattern 120A of the printed circuit board 100A according to an example embodiment, the seed metal layers 121 and 122 of the conductive pattern 120B do not include the third metal layer. Even in this case, the above-described technical effect may be achieved. Other descriptions are substantially the same as those described above, and therefore, redundant descriptions are omitted.

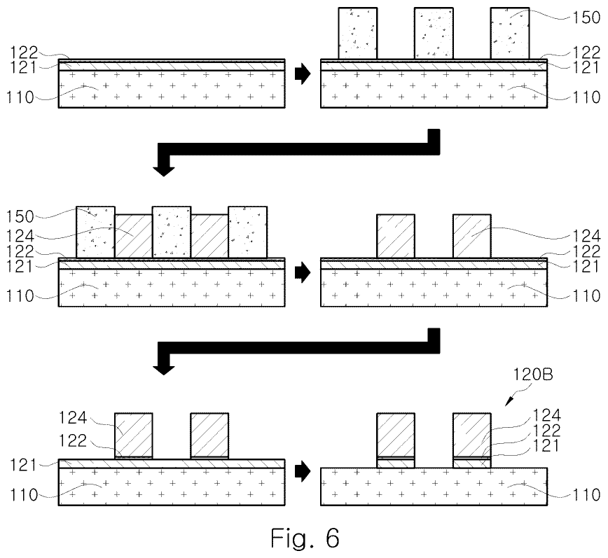

FIG. 6 is a process diagram schematically illustrating an example of manufacturing the printed circuit board of FIG. 5.

Referring to FIG. 6, first, seed metal layers 121 and 122 are formed on an insulating substrate 110. The seed metal layers 121 and 122 may be formed, for example, in a sputtering process (e.g., DC Sputter), and the first metal layer 121 as a compensation layer and the second metal layer 122 as a seed layer may be formed in order. Next, a photoresist mold 150 is formed on the second metal layer 122, and a space for forming a microcircuit pattern is patterned by an exposure and development process, or the like. Next, a pattern metal layer 124 is formed on the second metal layer 122 exposed through the opening of the photoresist mold 150 by electrolytic plating, for example, electrolytic copper plating. Next, the photoresist mold 150 is stripped and removed. Next, the second metal layer 122 of an unnecessary region is removed by wet etching, for example, an etchant. Next, the first metal layer 121 of an unnecessary region is removed by dry etching, for example, Reactive Ion Etching (RIE). Through this process, a printed circuit board 100B according to another example embodiment having the above-described technical effect may be manufactured. Since other details are substantially the same as those described above, redundant descriptions thereof will be omitted.

Hereinafter, the technical effects of the printed circuit board 100B according to another example embodiment will be described in more detail through experiments.

### Example 4

In Example 1, the seed metal layer was changed in order to confirm whether there were any problems with plating and bonding when the seed metal layer was formed only with the molybdenum (Mo) layer and the seed copper (Cu) layer as compensation layers, excluding the titanium (Ti) layer as a bonding layer from the seed metal layer. That is, the molybdenum (Mo) layer and the copper (Cu) layer were deposited in order on the organic insulating layer by a sputtering process by a thickness of about 1500 Å and 500 Å, respectively, to form a seed metal layer having a stack structure. In this case, the total conductance of the seed metal layer was calculated to be about 575×10⁻² Ω⁻¹. The rest of the experiment was conducted in the same manner. Even when the titanium (Ti) layer as the bonding layer was omitted, plating proceeded normally, and although the adhesion of the seed metal layer may decrease, but similarly, in the final micropattern, undercut due to the reduction in the thickness of the seed copper (Cu) layer was barely observed, and the micropattern was also formed with almost no delamination.

### Example 5

In order to confirm that there was no problem with electroplating even when the thickness of the seed copper (Cu) layer was further reduced than in Example 4, the seed metal layer was changed. That is, a molybdenum (Mo) layer and a copper (Cu) layer were deposited in order on the organic insulating layer by a sputtering process by a thickness of about 1500 Å and 300 Å, respectively, to form a seed metal layer having a stack structure. In this case, the total conductance of the seed metal layer was calculated to be about 459×10⁻² Ω⁻¹. The rest of the experiment was conducted in the same manner. Even when the thickness of the seed copper (Cu) layer became thinner, the plating proceeded normally, and the adhesion of the seed metal layer may decrease, but similarly, in the final micropattern, undercut due to the reduction in the thickness of the seed copper (Cu) layer was barely observed, and the micropattern was also formed with almost no delamination.

### Reference Example 2

In Example 4, the seed metal layer was changed to confirm whether there was no problem with electroplating even when the seed copper (Cu) layer was changed to a seed titanium (Ti) layer. That is, a molybdenum (Mo) layer and a titanium (Ti) layer were deposited in order on the organic insulating layer by a sputtering process by a thickness of about 1500 Å and 500 Å, respectively, to form a seed metal layer having a stack structure. In this case, the total conductance of the seed metal layer was calculated to be about 296×10⁻² Ω⁻¹. The rest of the experiment was conducted in the same manner. Copper (Cu) was used for electroplating to form a micropattern, and when a seed titanium (Ti) layer is used instead of a seed copper (Cu) layer, this may be disadvantageous for copper (Cu) nucleation and the total conductance may decrease. Accordingly, plating failure may occur.

### Reference Example 3

In Example 5, the seed metal layer was changed to confirm whether a problem occurred in electroplating even when the thickness of the molybdenum (Mo) layer as the compensation layer was increased. That is, a molybdenum (Mo) layer and a titanium (Ti) layer were deposited in order on the organic insulating layer by a sputtering process by a thickness of about 4000 Å and 500 Å, respectively, to form a seed metal layer having a stack structure. In this case, the total conductance of the seed metal layer was calculated to be about 769×10⁻² Ω⁻¹. The rest of the experiment was conducted in the same manner. Copper (Cu) was used for electroplating to form a micropattern. However, when a seed titanium (Ti) layer is used instead of a seed copper (Cu) layer, this may be disadvantageous for copper (Cu) nucleation. Accordingly, despite the high total conductance, plating defects may occur.

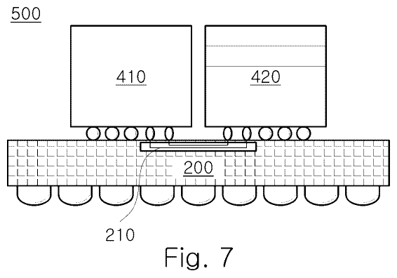

FIG. 7 is a cross-sectional view schematically illustrating an example of a semiconductor package.

Referring to FIG. 7, a semiconductor package 500 according to an example embodiment may include a package substrate 200 and first and second semiconductor chips 410 and 420 mounted on the package substrate 200. A bridge substrate 210 including fine interconnection lines interconnecting the first and second semiconductor chips 410 and 420 may be embedded in the package substrate 200. The bridge substrate 210 may include at least one of the printed circuit boards 100A and 100B described above as an internal structure. For example, the bridge substrate 210 may have an interconnection structure including one or more insulating layers, one or more interconnection layers respectively disposed on or in one or more insulating layers, and one or more via layers respectively penetrating through at least one of the insulating layers, and in this case, at least one of the one or more insulating layers may include the above-described insulating substrate, and at least one of the one or more interconnection layers may include the above-described plurality of conductive patterns. The package substrate 200 may be a typical multilayer printed circuit board, and a specific structure thereof is not particularly limited. If necessary, at least one of the printed circuit boards 100A and 100B described above may be included as an internal structure of the package substrate 200. The first and second semiconductor chips 410 and 420 may be memory chips, application processor chips, and/or logic chips, respectively. The first and second semiconductor chips 410 and 420 may be the same type of chips or different types of chips. Other details are substantially the same as described above, and redundant descriptions thereof will be omitted.

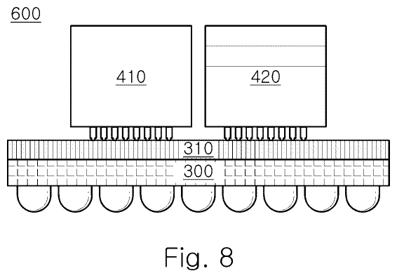

FIG. 8 is a cross-sectional view schematically illustrating another example of a semiconductor package.

Referring to FIG. 8, a semiconductor package 600 according to another example embodiment may include a package substrate 300 and first and second semiconductor chips 410 and 420 mounted on the package substrate 300. A fine interconnection layer 310 including fine interconnection lines interconnecting the first and second semiconductor chips 410 and 420 may be disposed on an outermost side of the package substrate 300. The fine interconnection layer 310 may include at least one of the printed circuit boards 100A and 100B described above. For example, the fine interconnection layer 310 may have an interconnection structure including at least one insulating layer, at least one interconnection layer respectively disposed on or in at least one insulating layer, and at least one via layer respectively penetrating through at least one of the one or more insulating layers, and in this case, at least one of the one or more insulating layers may include the above-described insulating substrate, and at least one of the one or more interconnection layers may include the above-described plurality of conductive patterns. The package substrate 300 may be a typical multilayer printed circuit board, and a specific structure thereof is not particularly limited. If necessary, the internal structure of the package substrate 300 may include at least one of the above-described printed circuit boards 100A and 100B. The first and second semiconductor chips 410 and 420 may be memory chips, application processor chips, and/or logic chips, respectively. The first and second semiconductor chips 410 and 420 may be the same type of chips or different types of chips. Other details are substantially the same as described above, and redundant descriptions thereof will be omitted.

In the present disclosure, the electrical resistivity of the metal may be, for example, the volume electrical resistivity or the bulk electrical resistivity of the metal. Electrical resistivity may be obtained from electrical resistance measurements from, for example, a multimeter. Other methods and/or tools appreciated by one of ordinary skill in the art, even if not described in the present disclosure, may also be used.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of partially filling, and may also include a case of approximately filling. Additionally, the expression ‘surrounding’ may include not only a case of completely surrounding but also a case of partially surrounding and a case of approximately surrounding. Additionally, exposing may include partial exposing as well as a case of complete exposing, and exposure may refer to exposure from embedding a corresponding component.

In the present disclosure, determination may be performed by including process errors, positional deviations, errors at the time of measurement, which may occur substantially in a manufacturing process. For example, substantially constant thickness may include not only a case in which the thickness is completely constant, but also a case in which the thickness is approximately constant. Furthermore, being substantially coplanar may include not only a case in which elements are completely on the same plane, but also a case in which the elements are approximately on the same plane.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, an aspect ratio, a depth, a line width, an interval, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points. Other methods and/or tools appreciated by one of ordinary skill in the art, even if not described in the present disclosure, may also be used.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a conductive pattern including a seed metal layer and a pattern metal layer disposed on the seed metal layer,
wherein the seed metal layer includes a first metal layer including a first metal, and a second metal layer disposed on the first metal layer and connected to the pattern metal layer and including a second metal,
wherein the first metal layer has a thickness thicker than the second metal layer, and
wherein the first metal is one selected from the group consisting of aluminum (Al), iridium (Ir), molybdenum (Mo), tungsten (W), cobalt (Co), nickel (Ni), and ruthenium (Ru).

2. The printed circuit board according to claim 1,
wherein the second metal has a lower electrical resistivity than the first metal.

3. The printed circuit board according to claim 2,
wherein the second metal is copper (Cu).

4. The printed circuit board according to claim 1,
wherein each of the first and second metal layers is a sputter thin film,
the first metal is molybdenum (Mo), and
the second metal is copper (Cu).

5. The printed circuit board according to claim 1,
wherein the seed metal layer further includes a third metal layer including a third metal,
the third metal layer, the first metal layer, and the second metal layer are stacked in order based on a thickness direction, and
the first metal layer is thicker than the third metal layer.

6. The printed circuit board according to claim 5,
wherein the third metal has a higher electrical resistivity than the first metal.

7. The printed circuit board according to claim 6,
wherein the third metal is one selected from the group consisting of chromium (Cr), tantalum (Ta), niobium (Nb), and titanium (Ti).

8. The printed circuit board according to claim 5,
wherein each of the first to third metal layers are a sputter thin film,
the first metal is molybdenum (Mo),
the second metal is copper (Cu), and
the third metal is titanium (Ti).

9. The printed circuit board according to claim 1,
wherein the pattern metal layer is thicker than the seed metal layer, and
the pattern metal layer includes the same metal as the second metal.

10. The printed circuit board according to claim 9,
wherein the pattern metal layer is an electrolytic plating layer, and
the pattern metal layer includes copper (Cu).

11. The printed circuit board according to claim 1,
wherein the first metal has an electrical resistivity of 10×10⁻⁸ Ω*m or less,
the second metal layer has a thickness of 1000 Å or less, and
a total conductance of the seed metal layer is 350×10⁻² Ω⁻¹ or more.

12. The printed circuit board according to claim 1,
wherein the conductive pattern includes a plurality of micropatterns adjacent to each other,
at least one micropattern among the plurality of micropatterns includes the seed metal layer and the pattern metal layer,
each of the plurality of micropatterns has a width of 2μm or less,
an interval between adjacent micropatterns among the plurality of micropatterns is 2μm or less, and
each of the plurality of micropatterns has an aspect ratio of 1 or more.

13. The printed circuit board according to claim 1, further comprising:
an insulating substrate,
wherein the conductive pattern is in contact with at least one surface of the insulating substrate.

14. The printed circuit board according to claim 13,
wherein the printed circuit board has a multilayer interconnection structure including at least one insulating layer, at least one interconnection layer disposed on or in the at least one insulating layer, and at least one via layer penetrating through at least one of the at least one insulating layer,
at least one of the at least one insulating layer includes the insulating substrate, and
at least one of the at least one interconnection layer includes the conductive pattern.

15. The printed circuit board according to claim 12, wherein the second metal layer has a thickness of 50 Å to 1000 Å.

16. The printed circuit board according to claim 12,
wherein the seed metal layer further includes a third metal layer including a third metal,
the third metal layer, the first metal layer, and the second metal layer are stacked in order based on a thickness direction,
the first metal layer is thicker than the third metal layer,
the first metal is molybdenum (Mo),
the second metal is copper (Cu), and
the third metal is titanium (Ti).

17. The printed circuit board according to claim 16, the pattern metal layer includes copper (Cu).

18. A printed circuit board, comprising:
an insulating substrate; and
a conductive pattern including a seed metal layer disposed on the insulating substrate and a pattern metal layer disposed on the seed metal layer,
wherein the seed metal layer has a stack structure including a titanium (Ti) layer, a molybdenum (Mo) layer, and a first copper (Cu) layer stacked in order.

19. The printed circuit board according to claim 18,
wherein the pattern metal layer includes a second copper (Cu) layer, and
the first copper (Cu) layer and the second copper (Cu) layer are in contact with each other.

20. The printed circuit board according to claim 18,
wherein the pattern metal layer is thicker than the seed metal layer, and
in the stack structure the molybdenum (Mo) layer is thicker than each of the titanium (Ti) layer and the first copper (Cu) layer.
